(19) United States
(12) Patent Application Publication
(10) Pub. No.: US 2026/0120996 A1
(43) Pub. Date: Apr. 30, 2026

(54) RF ASSEMBLY FOR SUBSTRATE PROCESSING SYSTEMS

(71) Applicant: LAM RESEARCH CORPORATION, Fremont, CA (US)

(72) Inventors: Miguel Benjamin VASQUEZ, Portland, OR (US); David FRENCH, Fort Myers, FL (US)

(21) Appl. No.: 18/836,104

(22) PCT Filed: Feb. 7, 2023
(86) PCT No.: PCT/US2023/012470

§ 371 Date: Aug. 6, 2024

Related U.S. Application Data
(60) Provisional application No. 63/313,295, filed on Feb. 24, 2022.

(51) Int. Cl. H01J 37/32

(52) U.S. Cl. CPC H01J 37/321; H01J 37/32183; H01J 2237/332; H01J 2237/334

(57) ABSTRACT

An inductor strap for a radio frequency matching circuit of a substrate processing system comprises a first end and a second end each comprising a respective connector tab configured to connect to a terminal of a respective capacitor, an inductor coil disposed between the first end and the second end, and an intermediate portion disposed between the inductor coil and one of the first end and the second end. The intermediate portion comprises a planar connection plate configured to couple the inductor strap to a surface of a radio frequency enclosure that houses the radio frequency matching circuit.

### CROSS-REFERENCE TO RELATED APPLICATIONS

This application claims the benefit of U.S. Provisional Application No. 63/313,295 filed on Feb. 24, 2022. The entire disclosure of the above application is incorporated herein by reference.

### FIELD

The present disclosure relates to radio frequency (RF) assemblies for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems or tools are used to perform treatments such as deposition and etching of film on substrates such as semiconductor wafers. For example, deposition may be performed to deposit conductive film, dielectric film, or other types of film using chemical vapor deposition (CVD), plasma enhanced CVD (PECVD), atomic layer deposition (ALD), plasma enhance ALD (PEALD), and/or other deposition processes. During deposition, the substrate is arranged on a substrate support and one or more precursor gases may be supplied to a processing chamber during one or more process steps. In a PECVD or PEALD process, plasma is used to activate chemical reactions within the processing chamber during deposition.

Some processing chambers comprise multiple stations. Each station may comprise a substrate support and a showerhead. A robot is configured to transfer the substrate from one station to another.

### SUMMARY

An inductor strap for a radio frequency matching circuit of a substrate processing system comprises a first end and a second end each comprising a respective connector tab configured to connect to a terminal of a respective capacitor, an inductor coil disposed between the first end and the second end, and an intermediate portion disposed between the inductor coil and one of the first end and the second end. The intermediate portion comprises a planar connection plate configured to couple the inductor strap to a surface of a radio frequency enclosure that houses the radio frequency matching circuit.

In other features, the inductor strap is comprised of copper. The first end, the second end, the inductor coil, and the intermediate portion are formed from a single piece of conductive material. The inductor strap has at least one change of direction between the first end and the second end. The inductor strap comprises a horizontal portion and a vertical portion. The inductor coil and the intermediate portion are located in the horizontal portion of the inductor strap. The inductor coil is located substantially below a plane defined by the intermediate portion. The intermediate portion comprises at least one opening defined in the connection plate. The at least one opening comprises two elongated slots.

In other features, a radio frequency matching circuit comprises the inductor strap and further comprises a first capacitor and a second capacitor. The inductor strap is coupled between the first capacitor and the second capacitor. The first capacitor has a first orientation and the second capacitor has a second orientation different from the first orientation. The second orientation is perpendicular to the first orientation. A horizontal portion of the inductor strap is coupled to the first capacitor and a vertical portion of the inductor strap is coupled to the second capacitor. A support bar is coupled to the intermediate portion and the surface. At least one of an inductance element, a resistance element, a capacitance element, and an insulative element is coupled to the intermediate portion at a location of the support bar. The surface is a lower surface of a top plate of the radio frequency enclosure.

A radio frequency enclosure comprises the radio frequency matching circuit and a top plate. The intermediate portion of the inductor strap is coupled to a lower surface of the top plate via a support bar. The radio frequency enclosure further comprises a plurality of the radio frequency matching circuits each configured to output a radio frequency signal to a respective radio frequency connector assembly mounted on an upper surface of the top plate. The radio frequency connector assembly comprises a right angle connector and a connector bracket configured to partially enclose the right angle connector. The connector bracket comprises a mounting base coupled to the upper surface of the top plate and a connector housing configured to retain the right angle connector within the connector bracket.

A radio frequency enclosure for a substrate processing system comprises a top plate and a plurality of radio frequency matching circuits mounted on a lower surface of the top plate. Each of the plurality of radio frequency matching circuits comprises first and second capacitors and an inductor strap coupled between respective terminals of the first and second capacitors. The inductor strap comprises an inductor coil and an intermediate portion. The intermediate portion comprises a planar connection plate configured to couple the inductor strap to the lower surface of the top plate. An insulative support bar couples the intermediate portion of the inductor strap to the lower surface of the top plate. A plurality of radio frequency connector assemblies is mounted on an upper surface of the top plate and coupled to respective ones of the radio frequency matching circuits. Each of the radio frequency connector assemblies comprises a right angle connector and a connector bracket partially enclosing the right angle connector.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing tool comprising multiple stations with pedestals for processing substrates and an RF enclosure for housing RF assemblies for the multiple stations;

FIG. 2A shows an isometric view of the RF enclosure of FIG. 1;

FIG. 2B shows a plan view of a top plate of the RF enclosure;

FIGS. 3A and 3B show an example connector bracket for a right angle RF output connector;

FIG. 3C shows an example RF connector assembly comprising the connector bracket and a right angle RF output connector;

FIG. 4A is a functional block diagram of an example RF generator assembly,

FIG. 4B is an example matching network of an RF matching circuit;

FIGS. 5A and 5B show example inductor straps for an RF matching circuit; and

FIG. 5C shows an example intermediate portion of the inductor straps of FIGS. 5A and 5B.

In the drawings, reference numbers may be reused to identify similar and/or identical elements.

### DETAILED DESCRIPTION

A substrate processing system may comprise one or more radio frequency (RF) assemblies comprising an RF generator and associated components, such as tuning and/or matching circuits or assemblies, filter modules (e.g., filter boxes) enclosing RF filter, matching, and/or tuning circuits, etc. In some examples, RF assembly components may be disposed on or adjacent to and/or integrated with a wall of a processing tool. For example, RF assembly components may be disposed adjacent to a first surface (e.g., a top or upper surface) or a second surface (e.g., a bottom or lower surface) of the processing tool.

In some examples, RF assembly components for multiple processing stations (e.g., four processing stations in a quad-station processing tool) are housed in an RF enclosure below the processing tool. Connections between the RF assembly components (e.g., cables for RF output connections) pass through a top plate or cover of the RF enclosure to connect to corresponding inputs of the processing stations.

In substrate processing systems and methods according to the present disclosure, an RF connector assembly for an RF assembly is configured to provide a secure interface between an RF generator and an RF cable coupled to a respective processing station. For example, the RF connector assembly comprises a connector bracket mounted on the top plate of the RF enclosure. The connector bracket is configured to house a right angle connector that couples the RF cable to the RF generator. The connector may comprise one or more cutouts configured to accommodate the right angle connector and/or an RF cable connector. In this manner, the connector bracket relieves stress on the RF cable and improves connector layout.

In some examples, the RF connector assembly is coupled to an RF matching circuit within the RF enclosure. The RF matching circuit comprises an inductor strap coupled between capacitors of the RF matching circuit. The inductor strap comprises a planar intermediate portion located between an inductor (e.g., an inductor coil of the inductor strap) and one of the capacitors. The intermediate portion is configured to provide a rigid attachment point to fixedly attach the inductor strap to the RF enclosure (e.g., the top plate of the RF enclosure). In one example, the intermediate portion is attached to the top plate of the RF enclosure using a rigid insulator structure, such as an insulator bar comprising amorphous thermoplastic polyetherimide (PEI) material.

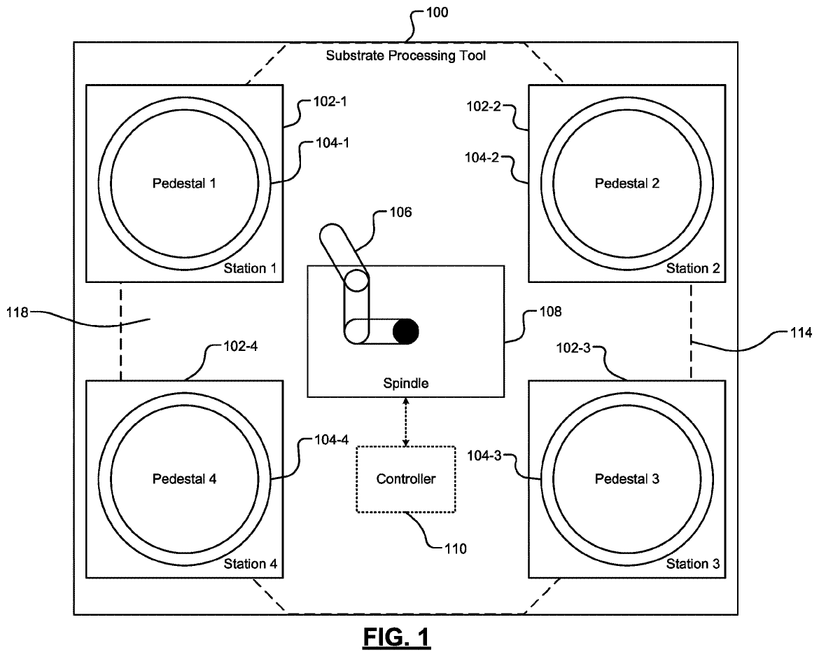

FIG. 1 shows a plan view of a substrate processing system or tool 100 comprising a plurality of stations 102-1, 102-2, 102-3, and 102-4 (collectively referred to as stations 102). While four stations 102 are shown for example only, the processing chamber 100 may comprise any number of stations. The stations 102 respectively comprise pedestals 104-1, 104-2, 104-3, and 104-4 (collectively referred to as pedestals 104). In some examples, the pedestals 104 are configured to be moved (e.g., raised and lowered) by respective pedestal lift assemblies. A robot 106 is arranged on a spindle 108 to transfer substrates between the stations 102. A controller 110, which is typically located outside the processing chamber 100 (and hence shown in dashed lines), controls the robot 106 and the pedestal lift assemblies.

An RF enclosure 114 is disposed below the substrate processing tool 100. The RF enclosure 114 houses RF assembly components (e.g., a high frequency (HF) power supply and associated components, not shown in FIG. 1) for respective ones of the stations 102. Connections between the RF assembly components (e.g., cables for RF output connections) a routed through a top plate 118 of the RF enclosure 114 to connect to corresponding inputs (e.g., RF inputs) of the stations 102. The RF enclosure 114 according to the present disclosure comprises an RF connector assembly and connector bracket mounted on the top plate 118 as described below in more detail.

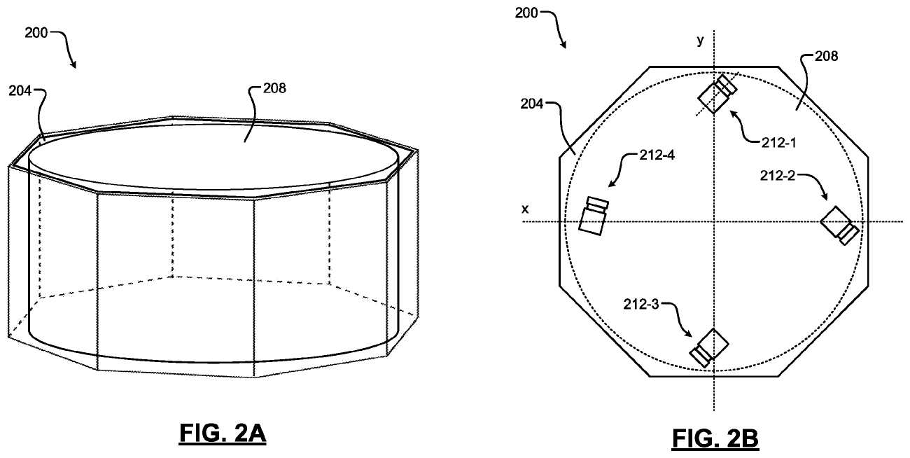

FIGS. 2A and 2B shows a simplified example of an RF enclosure 200 and a top plate 204. For example only, the RF enclosure 200 is octagonal in shape. Alternatively, the RF enclosure 200 can have any other shape. The RF enclosure 200 houses an RF assembly 208 (e.g., shown schematically) and associated components, such as RF generator, tuning or matching, and filter circuitry. For example, the RF assembly 208 may implement a matching circuit configured to control RF voltages supplied to the stations 102. The matching circuit may comprise variable or fixed impedances, capacitances, etc.

In some examples, the RF assembly 208 outputs RF signals to the stations 102 via respective connector assemblies 212 mounted on the top plate 204. For example, signals are routed from the RF assembly 208 through the top plate 204 (e.g., using respective cables) and to the connector assemblies 212, which are in turn connected to RF inputs of the stations 102. For example, for a quad station processing tool, four of the connector assemblies 212 (212-1, 212-2, 212-3, and 212-4) are mounted on the top plate 204 as shown.

The connector assemblies 212 according to the present disclosure are oriented to optimize cable routing, shorten cable lengths between the connector assemblies 212 and the stations 102, and relieve stress on cable connections. One or more of the connector assemblies 212 is orientated at a rotation approximately 45 degrees (e.g., between 40 and 50 degrees) from a center y axis of the RF enclosure 200 with a connector end pointing in an outward direction relative to the center of the RF enclosure 200. As shown, three of the connector assemblies 212 (e.g., 212-1, 212-2, and 212-3) have a same orientation relative to the y axis (e.g., 45 degrees) and point outward (i.e., outward towards a nearest outer edge of the RF enclosure 200. Conversely, the connector assembly 212-4 has a different orientation (e.g., 15 degrees) relative to the y axis. Further, the connector assembly 212-4 points inward (i.e., inward and away from a nearest outer edge of the RF enclosure 200).

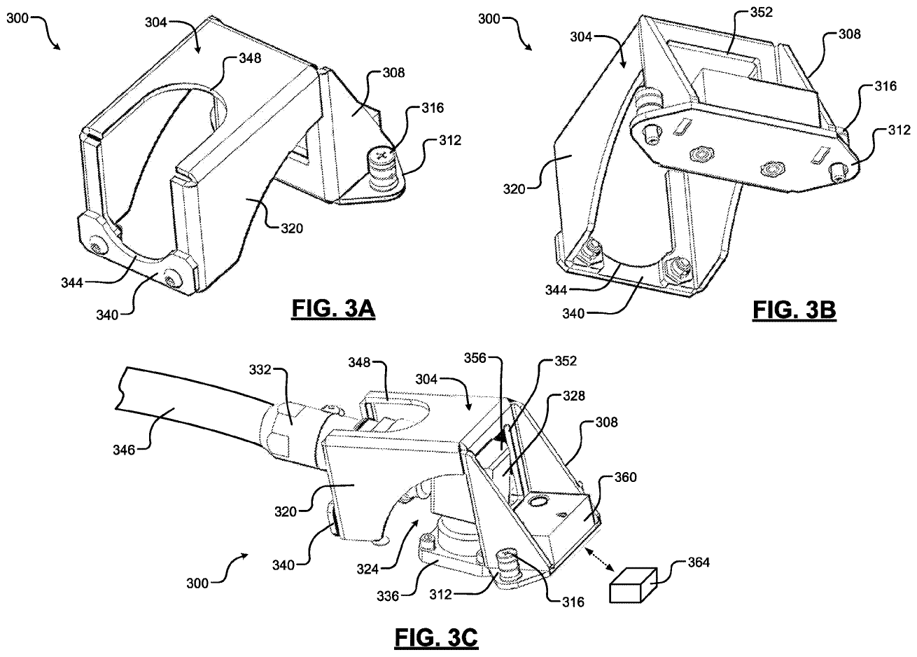

An example RF connector assembly 300 according to the present disclosure is shown in more detail in FIGS. 3A, 3B, and 3C. For example, the RF connector assembly 300 comprises a connector bracket 304 mounted on the top plate 204 of the RF enclosure 200. The connector bracket 304 may be comprised of welded sheet metal. In one example, the connector bracket 304 comprises a mounting base 308 with tabs 312. The connector bracket 304 is fastened to the top plate 204 with screws 316 (e.g., self-clinching sheet metal screws) inserted through the tabs 312.

The connector bracket 304 further comprises a connector housing 320 coupled (e.g., welded) to or integrally formed with the mounting base 308. The connector housing 320 is configured to retain, align, and support a right angle connector 324 (e.g., an RF output connector) within the connector bracket 304. For example, the right-angle connector 324 comprises a vertical portion 328 that extends upward from the top plate 204 and a horizontal portion 332 that extends outward from the vertical portion 328. The vertical portion 328 is perpendicular to the top plate 204. The horizontal portion 332 is perpendicular to the vertical portion 328 and parallel to the top plate 204. For example only, the vertical portion 328 comprises a mounting flange 336 for fastening the right-angle connector to the top plate 204.

The connector housing 320 may comprise a support plate 340 disposed below the horizontal portion 332 of the right angle connector 324. For example, the support plate 340 has a convex edge 344 (e.g., a cutout) configured to accommodate the horizontal portion 332. In some examples, the support plate 340 is removable (i.e., removable from a body of the connector housing 320). In this manner, with the support plate 340 removed, the connector bracket 304 can be removed and/or replaced without removing disconnecting a corresponding RF cable 346. Conversely, with the support plate 340 installed, the connector bracket 304 is retained on the right angle connector 324 and the RF cable 346.

The connector bracket 304 may comprise one or more cutouts configured to accommodate and/or facilitate access to the right angle connector 324 (e.g., to connect and disconnect the RF cable). For example, an upper surface or wall of the connector housing 320 may comprise a first cutout 348 (e.g., a convex cutout) configured to allow access to the horizontal portion 332 of the right angle connector 324. Conversely, a second cutout 352 (e.g., a rectangular cutout) defined in a rear sidewall of the connector bracket 304 between the connector housing 320 and the mounting base 308 is configured to accommodate an outer corner 356 of the right angle connector 324. The outer corner 356 corresponds to an interface or junction between the vertical portion 328 and the horizontal portion 332. In other words, the outer corner 356 of the right angle connector 324 may partially extend through the second cutout 352. The cutouts 348 and 352 facilitate installation and removal of the connector bracket 304 while the right angle connector 324 is already installed.

In some examples, the connector bracket 304 comprises a connection sensor 360. For example, the connection sensor 360 is a rectangular magnetic sensor disposed on the mounting base 308. The connection sensor 360 is configured to interface (e.g., magnetically communicate with) with a corresponding sensor 364 within the RF enclosure 200 on an opposite side of the top plate 204. For example, the sensor 364 is configured to detect the presence or absence of the connection sensor 360. In this manner, the sensor 364 may generate a signal indicative of whether the connector bracket 304 is installed.

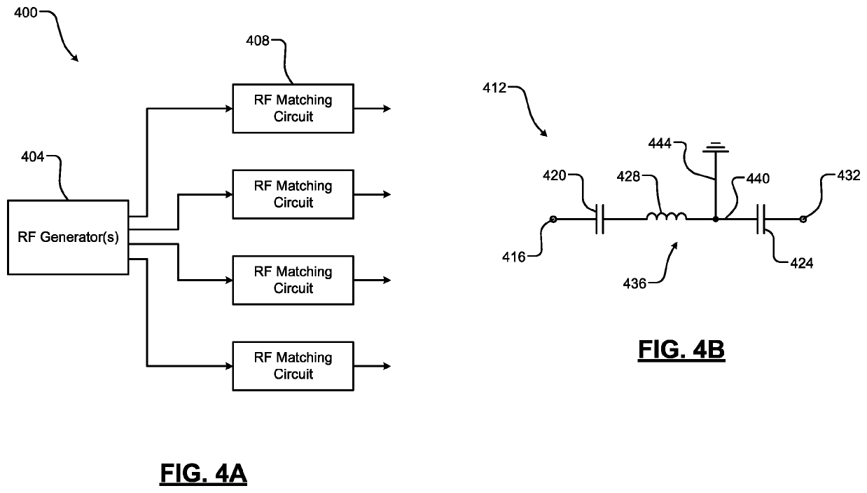

Referring now to FIGS. 4A and 4B, an example RF assembly 400 (e.g., an RF assembly housed within the RF enclosure 200) comprises one or more RF generators 404 and RF matching circuits 408. Although only one RF generator 404 is shown, the RF assembly 400 may comprise multiple RF generators (e.g., each corresponding to a different station 102. The RF generators 404 are configured to generate and output RF voltages to respective ones of the stations 102 through the RF matching circuits 408.

As shown in FIG. 4B, each of the RF matching circuits 408 comprises a corresponding matching network 412 configured to tune the RF voltage received from the RF generators 404. The matching network 412 is configured with an impedance that is tuned to a specific station, process, etc. The matching network 412 may be configured with a fixed and/or variable impedance. For example, the matching network 412 may comprise a plurality of components configured to provide a desired impedance.

In one example, the matching network 412 comprises an RF input node 416 (i.e., to receive the RF voltage from the corresponding RF generator 404), an inductor-capacitor network comprising capacitors 420 and 424 and an inductor 428 provided between the capacitors 420 and 424, and an RF output node 432. For example, the RF output node 432 is coupled to the right angle connector 324. One or both of the capacitors 420 and 424 may be an adjustable capacitor.

The matching network 412 according to the present disclosure comprises an inductor strap 436 coupled between the capacitors 420 and 424 as described below in more detail. The inductor strap 436 comprises the inductor 428 and an intermediate portion 440 disposed between the inductor 428 and one of the capacitors 420 and 424. The intermediate portion 440 is attached to the top plate 204 of the RF enclosure 200 (e.g., shown as a ground terminal) using a rigid structure, such as an insulative bar comprising amorphous thermoplastic polyetherimide (PEI) material, shown schematically at 444.

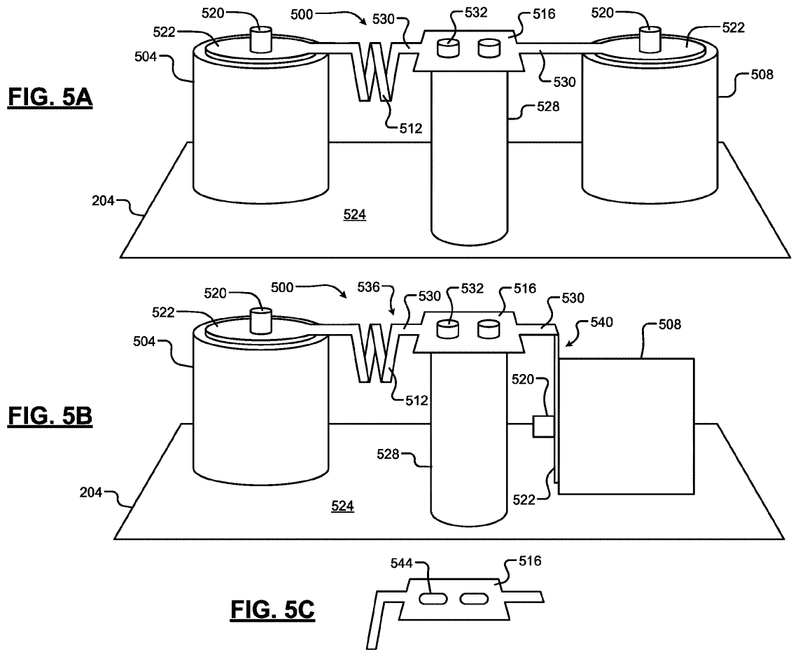

An example inductor strap 500 coupled between capacitors 504 and 508 in an RF matching circuit is shown in FIGS. 5A and 5B. One or both of the capacitors 504 and 508 may be adjustable. The inductor strap 500 comprises an inductor coil 512 and a planar intermediate portion 516 disposed between the inductor coil 512 and one of the capacitors 504 and 508. The planar intermediate portion 516 is at least partially planar. For example, although shown between the inductor coil 512 and the capacitor 508, in other embodiments the intermediate portion 516 may be disposed between the inductor coil 512 and the capacitor 504. The inductor strap 500 is coupled to the capacitors 504 and 508 via respective terminals 520. For example, the inductor strap 500 comprises connector tabs 522 (e.g., on respective first and second ends of the inductor strap 500) configured to connect to the terminals 520. In one example, the terminals 520 extend through openings in the connector tabs 522.

The inductor strap 500 is rigid (i.e., the inductor strap 500 is not a flexible cable). For example, the inductor strap 500 is a single, integral piece formed from a rigid conductive plate (e.g., a copper plate). The intermediate portion 516 is comprised of a connection plate that provides a rigid attachment point to fixedly attach the inductor strap 500 to the RF enclosure 200 (e.g., a lower surface 524 of the top plate 204, shown inverted in FIGS. 5A and 5B). Although shown as generally rectangular, the intermediate portion 516 may have other suitable shapes (e.g., trapezoidal, polygonal, triangular, diamond, circular, etc.). As shown, the inductor coil 512 is located substantially (e.g., 80% or more) below a plane defined by the intermediate portion 516.

In one example, the intermediate portion 516 is attached to the lower surface 524 of the top plate 204 using a rigid support structure (e.g., an insulative support bar 528, such as an insulative bar comprising amorphous thermoplastic polyetherimide (PEI) material). The intermediate portion 516 may be wider than the inductor coil 512, connecting portions 530, etc. to provide sufficient surface area for connecting to the support bar 528. For example, the inductor strap 500 flares outward from the inductor coil 512 and the connecting portions 530 to define the intermediate portion 516. The support bar 528 is coupled to the intermediate portion 516 using fasteners 532 (e.g., brass standoffs) and to the lower surface 524 of the top plate 204. The support bar 528 prevents movement of the inductor strap 500 during operation (e.g., movement caused by inadvertent contact with the inductor strap 500, movement caused by temperature fluctuation of the inductor strap 500 and/or thermal expansion caused by other components, etc.).

Although shown as being connected only to the support bar 528, in other examples the intermediate portion 516 may be connected to one or more other components of the within the RF enclosure 200. Since the support bar 528 provides rigid structural support for the inductor strap 500, the intermediate portion 516 can be configured to support multiple other mechanical and/or electro-mechanical connections. As one example, another (i.e., second) inductor strap may be couple to the inductor strap 500 at the intermediate portion 516. For example, an end of the second inductor strap may be coupled to the same fasteners 532 or to different fasteners. Other example components that may be connected to the intermediate portion 516 include, but are not limited to, an inductance element, a resistance element, a capacitance element, and an insulative element.

As shown in FIG. 5A, the inductor strap 500 is generally linear (e.g., in a horizontal direction). For example, the capacitors 504 and 508 may have the same vertical orientation (e.g., perpendicular to the top plate 204) and height and the inductor strap 500 may be coupled directly between the respective terminals 520. In other configurations, the capacitors 504 and 508 may not have the same orientation and/or height. For example, as shown in FIG. 5B, the inductor strap 500 may be configured to couple to the capacitor 504 in a vertical configuration and the capacitor 508 in a horizontal configuration (i.e., perpendicular to the capacitor 504).

In this example, the inductor strap 500 has at least one bend or change of direction and comprises a horizontal portion 536 and a vertical portion 540. The horizontal portion 536 comprises the inductor coil 512 and the intermediate portion 516. In other examples, the inductor strap 500 has two or more changes of direction. For example, while shown as generally linear in FIG. 5B, in other examples the horizontal portion 536 may have at least one change of direction. In one example, the horizontal portion 536 has a first change of direction between the capacitor 504 and the inductor coil 512 and a second change in direction between the inductor coil 512 and the intermediate portion 516. In different configurations, the inductor coil 512 and the intermediate portion 516 may both be located in the vertical portion 540, one of the inductor coil 512 and the intermediate portion 516 may be located in the horizontal portion 536 while the other is located in the vertical portion 540, etc. In any configuration, the inductor strap 500 comprises the intermediate portion 516 configured to provide a fixed attachment point for the support bar 528.

As shown in FIG. 5C, the intermediate portion 516 comprises opening, such as slots 544 (e.g., elongated slots), configured to receive the fasteners 532. Lengths of the slots 544 are greater than diameters of the fasteners 532. Accordingly, the slots 544 are configured to accommodate some movement of the inductor strap 500 relative to the support bar 528. In other words, if positions of either of the capacitors 504 and 508, the inductor strap 500, the support bar 528, etc. shift slightly due to thermal expansion or other variations, the slots 544 accommodate the shift without transferring movement to other components.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An inductor strap for a radio frequency matching circuit of a substrate processing system, the inductor strap comprising:
a first end and a second end, wherein each of the first end and the second end comprises a respective connector tab configured to connect to a terminal of a respective capacitor;
an inductor coil disposed between the first end and the second end; and
an intermediate portion disposed between (i) the inductor coil and (ii) one of the first end and the second end, wherein the intermediate portion comprises a planar connection plate configured to couple the inductor strap to a surface of a radio frequency enclosure that houses the radio frequency matching circuit.

2. The inductor strap of claim 1, wherein the inductor strap is comprised of copper.

3. The inductor strap of claim 1, wherein the first end, the second end, the inductor coil, and the intermediate portion are formed from a single piece of conductive material.

4. The inductor strap of claim 1, wherein the inductor strap has at least one change of direction between the first end and the second end.

5. The inductor strap of claim 4, wherein the inductor strap comprises a horizontal portion and a vertical portion.

6. The inductor strap of claim 5, wherein the inductor coil and the intermediate portion are located in the horizontal portion of the inductor strap.

7. The inductor strap of claim 6, wherein the inductor coil is located substantially below a plane defined by the intermediate portion.

8. The inductor strap of claim 1, wherein the intermediate portion comprises at least one opening defined in the connection plate.

9. The inductor strap of claim 8, wherein the at least one opening comprises two elongated slots.

10. A radio frequency matching circuit comprising the inductor strap of claim 1 and further comprising a first capacitor and a second capacitor, wherein the inductor strap is coupled between the first capacitor and the second capacitor.

11. The radio frequency matching circuit of claim 10, wherein the first capacitor has a first orientation and the second capacitor has a second orientation different from the first orientation.

12. The radio frequency matching circuit of claim 11, wherein the second orientation is perpendicular to the first orientation.

13. The radio frequency matching circuit of claim 12, wherein a horizontal portion of the inductor strap is coupled to the first capacitor and a vertical portion of the inductor strap is coupled to the second capacitor.

14. The radio frequency matching circuit of claim 10, further comprising a support bar coupled to the intermediate portion and the surface.

15. The radio frequency matching circuit of claim 14, wherein the surface is a lower surface of a top plate of the radio frequency enclosure.

16. The radio frequency matching circuit of claim 14, further comprising at least one of an inductance element, a resistance element, a capacitance element, and an insulative element coupled to the intermediate portion at a location of the support bar.

17. A radio frequency enclosure comprising the radio frequency matching circuit of claim 10 and a top plate, wherein the intermediate portion of the inductor strap is coupled to a lower surface of the top plate via a support bar.

18. The radio frequency enclosure of claim 17, further comprising a plurality of the radio frequency matching circuits, wherein each of the radio frequency matching circuits is configured to output a radio frequency signal to a respective radio frequency connector assembly mounted on an upper surface of the top plate.

19. The radio frequency enclosure of claim 18, wherein the radio frequency connector assembly comprises a right angle connector and a connector bracket configured to partially enclose the right angle connector.

20. The radio frequency enclosure of claim 19, wherein the connector bracket comprises a mounting base coupled to the upper surface of the top plate and a connector housing configured to retain the right angle connector within the connector bracket.

21. A radio frequency enclosure for a substrate processing system, the radio frequency enclosure comprising:
a top plate;
a plurality of radio frequency matching circuits mounted on a lower surface of the top plate, each of the plurality of radio frequency matching circuits comprising
first and second capacitors, and
an inductor strap coupled between respective terminals of the first and second capacitors, the inductor strap comprising an inductor coil and an intermediate portion, wherein the intermediate portion comprises a planar connection plate configured to couple the inductor strap to the lower surface of the top plate;
an insulative support bar that couples the intermediate portion of the inductor strap to the lower surface of the top plate; and
a plurality of radio frequency connector assemblies mounted on an upper surface of the top plate and coupled to respective ones of the radio frequency matching circuits, wherein each of the radio frequency connector assemblies comprises a right angle connector and a connector bracket partially enclosing the right angle connector.
